(19) United States
(12) Patent Application Publication
(10) Pub. No.: US 2008/0080265 A1
(43) Pub. Date: Apr. 3, 2008

(54) SEMICONDUCTOR MEMORY AND METHOD FOR TESTING SEMICONDUCTOR MEMORIES

(75) Inventors: Frank Fischer, Muenchen (DE); Thomas Lucia, Muenchen (DE); Juan Ocon, Muenchen (DE); Manfred Proell, Dorfen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/863,893

(22) Filed: Sep. 28, 2007

(30) Foreign Application Priority Data
Sep. 29, 2006 (DE) 10 2006 046 359.5

(51) Int. Cl. G11C 29/00; G11C 5/14; G11C 8/00

(52) U.S. Cl. 365/189.09; 365/201; 365/230.06

(57) ABSTRACT

A semiconductor memory and method for testing semiconductor memory is disclosed. One embodiment provides a method including activating a first master word line. An electric voltage difference between the first master word line and an adjacent master word line is generated. The leakage current between the first master word line and the adjacent master word line is measured.

### CROSS-REFERENCE TO RELATED APPLICATIONS

This Utility Patent Application claims priority to German Patent Application No. DE 10 2006 046 359.5 filed on Sep. 29, 2006, which is incorporated herein by reference.

### BACKGROUND

The invention relates to a semiconductor memory, in one embodiment a DRAM (Dynamic Random Access Memory). The invention relates further to a method for testing a semiconductor memory, in one embodiment for analyzing short circuits between master word lines of the semiconductor memory.

A memory field of DRAM memory cells usually consists of rows (word lines) and columns (bit lines). In today's DRAMs, the respective memory cells may substantially consist of capacitors. The capacitors of the memory cells are connected with bit lines which serve to transmit a data value that is to be read out from the memory cell, or a data value that is to be read into the memory cell.

During the reading out from a memory cell, an access transistor that is connected with the capacitor of a memory cell is connected through by the activation of a word line, and the charge state stored in the capacitor is applied to the bit line. The weak signal exiting from the capacitor is amplified by a sense amplifier.

In chronological order, first of all a word line is activated during an access to the memory, so that the memory cells arranged in a row are each conductively coupled with a bit line. At the end of the bit line, the sense amplifier is positioned which detects and amplifies the data content of the memory cell or the cell signal, respectively, transmitted via the bit line. The amplified signal is, on the one hand, written back in the cell via the bit line and can, on the other hand, be read out from the memory outward. This process is performed simultaneously for all memory cells that are assigned to a word line.

The actual reading out of the memory cell is accordingly performed in that corresponding word line signals connect through the access transistors that are connected with the memory capacitors. Then, corresponding activation voltages are applied to the sense amplifier, whereupon the sense amplifier amplifies the potential differences that are transmitted from the memory capacitors to the corresponding bit line sections, and outputs an amplified differential signal.

The amplified differential signal is transmitted from the sense amplifier to corresponding local data lines, wherein the local data lines are configured to be coupled to the sense amplifiers by corresponding transistors (“bit switches”). Two local data lines are respectively associated with each sense amplifier, which can be precharged differently as a function of a write or read access to the memory cell. The amplified differential signal is transmitted from the local data lines to global master word lines and may be transmitted to a further amplifier (so-called “secondary sense amplifier”) for further amplification.

Master word lines (MWLs) are, as a rule, formed in a metallization level of metallic material. Depending on whether the master word line is formed in the first or the second metallization level, it is called M1-MWL or M2-MWL. Due to the manufacturing of the master word lines of metallic material, the master word lines are often also referred to as metal word lines.

The above-described selection or activation of a word line is performed by impacting the corresponding word line with a positive voltage (VPP) that constitutes the highest positive voltage occurring in the memory chip. Contrary to this, the deselection or deactivation of a word line is performed by impacting the corresponding word line with a negative voltage (VNWLL) that constitutes the highest negative voltage occurring in the memory chip. The greatest potential difference consequently occurs in a memory chip if two adjacent word lines each have opposite maximum voltages.

During the manufacturing of memory devices, short circuits between line portions within a memory device may occur due to process weaknesses in the manufacturing procedure (e.g., due to defect density problems). These short circuits need not occur directly during the testing of the memory device immediately after the manufacturing process. Such short circuits between internal lines of the memory device may occur by thermo-electric activation only at a later time (e.g., at the consumer and further processor of the memory device), which may adversely influence the reliability assessment of the memory device.

The memory producer usually guarantees the customer a reliability performance in the dpm region (defects per millions of memory units). Such a guarantee is based on test methods in which the memory devices are artificially pre-aged by stress, i.e. the aging process of the memory devices is artificially accelerated. Typical reliability-relevant mechanisms occur here in an early operating phase of the stressed memory devices in the form of disproportionate failure probabilities. This way, a working, pre-aged memory device has a minor failure probability for the typical reliability-relevant mechanisms than a non-aged device.

The artificial aging of reliability mechanisms of the memory devices may, for instance, be achieved by excessive voltage and/or temperature increasing vis-à-vis normal operating conditions of the memory device. For the generation of word line stress, this is, however, only conditionally possible. In the word line drivers, a transistor has to block the voltage VPP+VNWLL (highest positive voltage in the memory chip (VPP)+highest negative voltage at the local word lines (VNWLL)). An excessive voltage increase during the stress may exceed the maximum block voltage of the word line driver transistors. During the exceeding of the maximum block voltage of the word line driver transistors high currents are flowing, which may lead to a thermal overstressing of the transistors. Therefore, only a reduced excessive voltage increase and thus a reduced voltage acceleration factor vis-à-vis normal operation of the memory device is possible for the word line stress.

The lower acceleration factor for the stress between adjacent word lines may, for instance, be compensated for by increasing the parallelism. In normal operation, only one word line per bank is activated in the memory device, wherein a critical voltage to the right and left word line neighbors (VNWLL) of the activated (VPP) word line is generated. In so doing, it is achieved by specific test modes that only every second local poly silicon word line is activated (VPP) during the stress impact. This way, each word line is “stressed” to its adjacent word line, which is also referred to as “word line stress” or “WL stress”.

Since the metal master word line selects four respective local poly silicon word lines, every metal master word line is ultimately activated during the selection of every second poly silicon word line (in the case of WL stress). The metal master word lines are consequently on the same potential, so that no sufficient stress takes place between master word lines (in the following referred to as “MWL stress”).

Some defect characteristics of memory devices, however, illustrate an increased proportion of short circuits between master word lines (MWL short circuits) in the case of defect density problems in the corresponding metallization level. Physical analyses of the MWL short circuits indicate two reasons, namely defects prior to the metallization and defects after the metallization. In the case of a defect prior to the metallization, the defect is, for instance, caused by particles below the master word line metal level (MWL metal level). In the case of a defect after the metallization, the defect is, for instance, caused by particles on the MWL metal level.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a schematic representation of a cross-section through the structure of a DRAM semiconductor memory to which the method for examining its reliability-relevant features in accordance with the invention can be applied.

FIG. 2A illustrates a schematic representation of a top view of the structure of a DRAM semiconductor memory illustrated in FIG. 1.

FIG. 2B illustrates an enlarged schematic representation of a part of the top view of the structure of a DRAM semiconductor memory illustrated in FIG. 2A.

FIG. 3 illustrates a schematic representation of the structure of a DRAM semiconductor memory for triggering the master word lines (MWL) and the pertinent local poly silicon word lines (GC-WL) which are each selectable via address bits X0 & X1.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

One or more embodiments provide an improved method for testing a semiconductor memory by which in one embodiment an efficient analysis of short circuits between master word lines of a semiconductor memory is possible. Another embodiment provides a semiconductor memory that enables a more efficient analysis of short circuits between master word lines of a semiconductor memory.

In accordance with one embodiment, there is provided a method for testing a semiconductor memory, wherein the semiconductor memory includes a number of master word lines and a number of local word lines which are each controllable via the master word lines, and at least one memory cell that stores a data value and is configured to be connected by using the local data lines via a circuit device, wherein the method includes the following processes:

activating a first master word line;

generating an electric voltage difference between the first master word line and an adjacent master word line; and

measuring the leakage current between the first master word line and the adjacent master word line.

In accordance with a further embodiment, the above-mentioned is solved by a semiconductor memory with a number of master word lines and a number of local word lines which are each controllable via the master word lines, and at least one memory cell that stores a data value and is configured to be connected by using the local data lines via a circuit device, wherein the memory includes a test register by the setting of which at least two adjacent master word lines can be controlled such during a test method that an electric voltage difference is generated between the adjacent master word lines.

By using the method according to the present invention and the semiconductor memory according to the invention it is possible to stress a master word line to an adjacent master word line and/or to an adjacent local word line, and to check the blocking thereof. Thus, an efficient analysis of short circuits between master word lines is possible during the testing of a semiconductor memory, as will be explained in more detail in the following.

As already mentioned above, the greatest potential difference occurs in a memory chip if, for instance, two adjacent word lines are each impacted with opposite voltages. This situation exists, for instance, if a word line is activated and an adjacent word line is deactivated. In this case, the activated word line is charged with the highest positive voltage (VPP) occurring in the memory chip, and the deactivated word line with the highest negative voltage (VNWLL) occurring in the memory chip. Between the asymmetrically charged word lines, the highest voltage difference now exists that occurs in the memory chip during normal operation, and may lead to short circuits between adjacent word lines in the case of defective memory chips with defect density problems.

The danger of short circuits between adjacent word lines is the higher the closer the corresponding word lines are together. Depending on the architecture of the memory, adjacent metal or master word lines may also be positioned particularly closely together, so that short circuits may be generated between the master word lines in the case of asymmetrical stressing thereof. The present invention therefore provides a method in which exactly the master word lines can be stressed to each other so as to check in one embodiment the reliable blocking of adjacent master word lines to each other.

For the analysis of short circuits between master word lines, for instance, master word lines and the pertinent poly silicon word lines (GC, “gate contact”) are triggered, which are selectable from an address decoder of the memory chip via address bits X0 & X1. There are two possibilities of addressing the MWL short circuits that have become visible:

a.) Extension of the driver transistors for increasing the electric strength in the stress case. Here, a direct influence on the chip size is to be expected, which multiplies with the number of word line driver circuits (MW test mode).

b.) Providing a master word line test mode that increases the parallelism of the word line stress for the master word lines similarly to that of poly silicon word lines. This means that every second master word line per test mode has to be activatable. Ideally, a combination of the WL test mode with the MWL test mode can be achieved.

There is further the possibility of activating poly silicon word lines at an interval of eight X-addresses by using a “Multiple Wordline Select” (MWLS) test mode. Thus, only every second master word line is activated. This has a plurality of disadvantages, though:

1.) asymmetrical poly silicon word line stress since only one out of four poly silicon word lines is activated;

2.) complex patterns for balancing the asymmetrical poly silicon word line stress, e.g., rotating through the X-start address, this in turn causing

3.) asymmetrical stress distribution of the master word lines by serial latching of the activated word lines,

4.) poly silicon word line stress as well as further related stress mechanisms, e.g., short circuits between poly silicon word lines (CBGC short circuits), cannot be decoupled from the MWL stress.

These problems are solved by a test mode in which either all “even” master word lines with even numbering are activated, or all “odd” master word lines with odd numbering are activated. As described above, there are sufficient different potentials present at adjacent MWLs, so that these can be utilized to detect potential isolation weaknesses between the master word lines or the metal master word lines, respectively. Thus, it is achieved that all metal master word lines are stressed to each other and the reduced acceleration factor may thus be compensated for by the excessive electric voltage increase. Thus, the stress for the metal MWL can be ensured, which leads to an improvement of the reliability of the memory devices for this stress mechanism.

In accordance with one embodiment, the direction of the voltage differences can be defined by the optional selection or activation of all “even” master word lines with even numbering or all “odd” master word lines with odd numbering.

In accordance with a further embodiment, a test mode is additionally used in which all “even” poly silicon word lines or all “odd” poly silicon word lines or all poly silicon word lines simultaneously are activated. For such a selection, a register of 2 bits would already be sufficient. To combine this “even” or “odd” selection or activation of the poly silicon word lines with the “even” or “odd” selection or activation of the master word lines (MWL), a register of 4 bits is, however, required in the memory chip.

| | |
|---|---|
| local poly sil. word line | master word line (MWL) |

| | | | |
|---|---|---|---|
| “even” | “odd” | “even” | “odd” |
| activate | activate | activate | activate |

If, for instance, all local poly silicon word lines are to be selected or activated, the bit for “even” and the bit for “odd” each have to be set to “1”. This applies in analogy to the selection or activation of the master word lines (MWLs). The following truth table may be composed thereof, wherein only 12 states out of the 16 possible states are useful. The states designated with “?” do not constitute any useful states since either no voltage potential is built up between adjacent word lines, or no master word line is activated.

| | | poly silicon WL | | MWL | | |
|---|---|---|---|---|---|---|
| state No. | useful effect | “even” | “odd” | “even” | “odd” | comment |
| 1 | | 0 | 0 | 0 | 0 | everything deactivated |
| 2 | only MWL | 0 | 0 | 0 | 1 | only “odd”, MWL stress |
| | stress | | | | | |
| 3 | only MWL | 0 | 0 | 1 | 0 | only “even” MWL stress |
| | stress | | | | | |
| 4 | ? | 0 | 0 | 1 | 1 | only MWLs active, no GC- |
| | | | | | | WL |
| 5 | ? | 0 | 1 | 0 | 0 | |
| 6 | GC-WL stress | 0 | 1 | 0 | 1 | only “odd” GC-WLs at “odd” |
| | & MWL stress | | | | | MWLs |
| 7 | GC-WL stress | 0 | 1 | 1 | 0 | only “odd” GC-WLs at |
| | & MWL stress | | | | | “even” MWLs |
| 8 | GC-WL stress | 0 | 1 | 1 | 1 | only “odd” GC-WL |
| 9 | ? | 1 | 0 | 0 | 0 | |
| 10 | GC-WL stress | 1 | 0 | 0 | 1 | only “even” GC-WLs at |
| | & MWL | | | | | “odd” MWLs |
| | stress | | | | | |
| 11 | GC-WL stress | 1 | 0 | 1 | 0 | only “even” GC-WLs at |
| | & MWL stress | | | | | “even” MWLs |
| 12 | GC-WL stress | 1 | 0 | 1 | 1 | only “even” GC-WL |
| 13 | ? | 1 | 1 | 0 | 0 | |
| 14 | CBGC stress | 1 | 1 | 0 | 1 | all GC-WLs at “odd” MWLs |
| | & MWL stress | | | | | |
| 15 | CBGC stress | 1 | 1 | 1 | 0 | all GC-WLs at “even” MWLs |
| | & MWL stress | | | | | |
| 16 | CBGC stress | 1 | 1 | 1 | 1 | all GC-WLs |

A state that is useful for the test method exists if two adjacent master word lines and/or two adjacent local word lines have a voltage potential to each other. This is achieved in that a master word line and an adjacent master word line are impacted with different voltages to each other, and/or in that a local word line and an adjacent local word line are impacted with different voltages to each other.

As described above, a different electric voltage between adjacent word lines is generated if the one word line is activated and is impacted with the positive voltage (VPP) and the other word line remains deactivated and therefore remains impacted with the negative voltage (VNWLL). A local word line can always only be activated if the pertinent master word line was also activated. Therefore, for instance, the state of number 5 is useless since a local word line is to be activated without activating the pertinent master word line.

Of the useful 12 states, the states with the numbers 1, 2, 3, 8, 12, 14, 15, and 16 are those useful states that can only be adjusted with the test mode according to the present invention. Altogether, eight useful states thus exist which can also be controlled with a register of only 3 bits. Consequently, the eight useful states mentioned can also be coded by using a register in the memory chip of only 3 bits.

As may be gathered from this truth table, the states with the numbers 1, 8, 12, and 16 are existing states, and the states with the numbers 2, 3, 14, and 15 are additional states that can be adjusted in accordance with the test mode according to the invention.

Further features and advantages of the present invention as well as preferred embodiments of the present invention will be described in the following with reference to the enclosed drawings.

It is to be understood that the features of the various exemplary embodiments described herein may be combined with each other, unless specifically noted otherwise.

Embodiments will now be described by referring to the enclosed drawings and with respect to some preferred embodiments. In the following description, numerous specific details are illustrated to explain the present invention. It is, however, obvious for a person skilled in the art that the present invention can be implemented without some or all of these specific details. On the other hand, known processes, circuits, and processes have not been described in detail so as not to obscure the present invention unnecessarily.

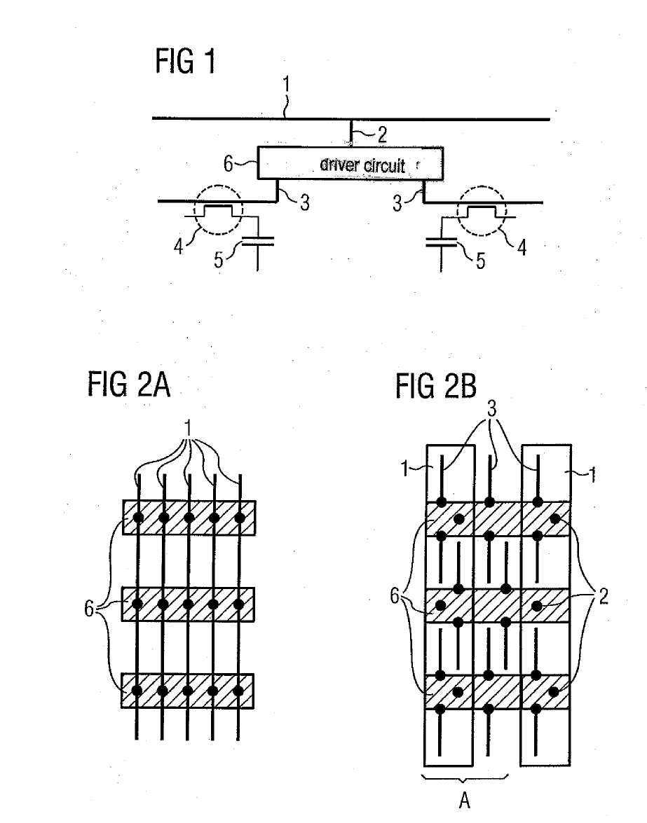

FIG. 1 illustrates one embodiment of a schematic representation of a cross-section through the structure of a DRAM memory that is configured to be subject to a test for examining its reliability-relevant features. For the purpose of short access times, word lines of semiconductor memories are provided with local word line drivers. In the structure of a DRAM semiconductor memory illustrated in FIG. 1, a metal master word line 1 is, via a master word line contact 2, coupled to a local driver circuit 6.

The local driver circuit 6 is, via a respective local poly silicon word line 3, connected with access transistors or cell transistors 4, respectively, of a DRAM memory cell. The cell transistors 4 of the memory cell are each coupled with a capacitor 5 in which the data content of the memory cell is stored. Thus, a global metal master word line 1 triggers a plurality of local poly silicon word lines 3. A decoding of the poly silicon word lines 3 may be performed directly in the local word line driver 6. FIG. 1 also illustrates that the master word lines 1 are positioned on another level (metallization level) than the local word lines 3.

FIG. 2A illustrates a schematic representation of a top view of the structure of a DRAM semiconductor memory illustrated in FIG. 1. FIG. 1 illustrates a horizontal master word line 1 while, in FIG. 2A, a plurality of master word lines 1 run vertically and cross a plurality of word line drivers 6. Via point-shaped master word line contacts 2, the master word lines 1 are, by the local driver circuits 6 and via the local poly silicon word lines 3, each connected with the cell transistors 4 of a DRAM memory cell.

FIG. 2B illustrates an enlarged schematic representation of a part of the view illustrated in FIG. 2A. By the enlarged representation, the master word lines 1 are broadened to form strips, so that the pertinent local word lines 3 as well as the point-shaped master word line contacts 2 on the driver circuits 6 are better to recognize. FIG. 2B also illustrates that the local poly silicon word lines 3 mesh in a finger-shaped manner and merely bridge the distance between two local driver circuits 6 and the master word line contacts 2 thereof.

To be able to sufficiently block the cell transistor 4 against the bit line (not illustrated) even at high temperatures, a negative voltage (VNWLL) has to be applied to the local poly silicon word lines 3. If the cell transistor 4 is not sufficiently blocked against the bit line, the electric charge of the memory cell will leak across the cell transistor 4 to the potential of the bit line. The leakage current generated this way will increase with the voltage difference between the corresponding memory cell 4, 5 and the bit line. The consequence is a reduced electric charge in the capacitor 5 of the memory cell and thus a lower reading potential of the memory cell to the bit line. This increases the probability of a wrong decoding of the data content of the memory cell by the sense amplifier, which may result in a loss of data.

To be able to read the full signal intensity back to the bit line with memory cells charged with bit line “high” potential (VBLH, “voltage bit line high”), a selected cell transistor 4 has to be triggered with a voltage that is at least by a starting voltage higher than the bit line “high” signal (VBLH). With some rate action, the “overdrive”, the highest available voltage (VPP) in the memory chip is therefore needed for the activation of the word line transistor. This signal is fed on the word line selected via the word line address. The adjacent poly silicon word lines are on the negative word line potential VNWLL. Like the local poly silicon word lines, the metal master word lines are triggered with VPP or VNWLL, respectively.

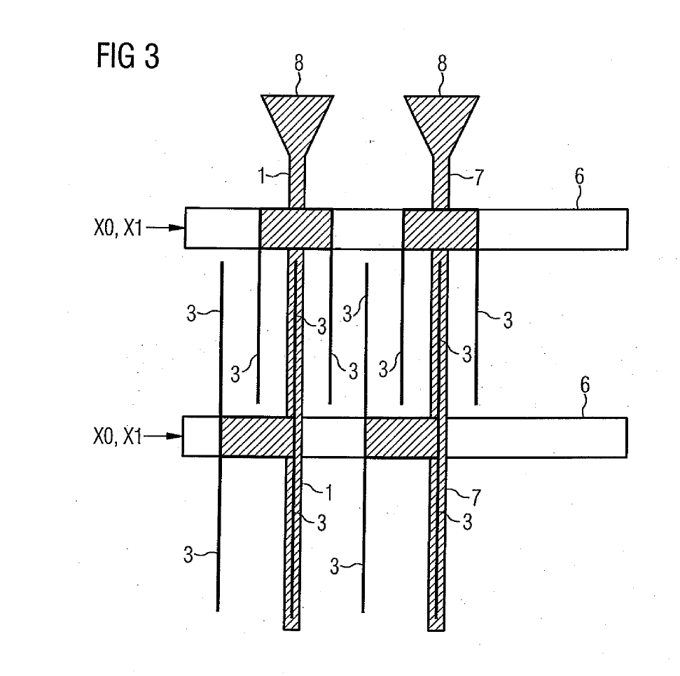

FIG. 3 illustrates the schematic structure of a DRAM semiconductor memory for representing the inventive triggering of the master word lines 1 (MWL) and the pertinent local poly silicon word lines 3 (GC-WL, “gate contact word line”). FIG. 3 illustrates a first master word line 1 and an adjacent second master word line 7, at the upper end of each of which a master word line driver circuit 8 is arranged. In the embodiment of the memory illustrated in FIG. 3, the master word lines 1 and 7 extend in parallel to each other and have a substantially vertical orientation. Four respective local word lines 3 are associated to each master word line 1 and 7, which can each be triggered via the corresponding master word lines 1 or 7, respectively.

The master word lines 1, 7 each cross local driver circuits 6 which establish the connection between the master word line 1, 7 and the pertinent local word lines 3, as already described with reference to FIG. 1. The driver circuits 6 obtain address bits X0 & X1 from the address decoder of the memory to trigger the desired local word lines 3. The local word lines 3 are each selectable via address bits X0 & X1.

The address bits X0 & X1 may be stored in a test register (not illustrated). In this test register, another address bit X2 may further be stored, which selects the master word line 1, 7. Thus, the test register of the semiconductor memory according to the invention preferably includes 3 bits to select the master word lines 1, 7 to be activated and the desired local word lines 3. The test register of the semiconductor memory according to the invention may, however, also include 4 or more bits so as to, for instance, additionally store information concerning the test mode to be performed or results of the test method.

In accordance with one embodiment, the generation of an electric voltage difference between the first master word line 1 and an adjacent master word line 7 is performed by applying opposite electric voltages. This may, for instance, be performed by deactivating at least one master word line 7 that is adjacent to the first master word line 1, while the first master word line 1 is activated.

In accordance with one embodiment, the activation of a number of master word lines is performed such that only “even” master word lines with even numbering are activated, while “odd” master word lines with odd numbering are deactivated. Accordingly, it is also possible to select a number of master word lines such that only “odd” master word lines with odd numbering are activated, while “even” master word lines with even numbering are deactivated. Alternatively or additionally, at least one local word line 7 that is adjacent to the first master word line 1 can be activated. Ultimately, all master word lines 1, 7 may be activated to be able to trigger all local word lines 3 and generate any voltage potentials therebetween.

The activation of a master word line 1, 7 or a local word line 3 may be performed by impacting the corresponding word line 1, 3, 7 with a positive voltage that constitutes the highest positive voltage occurring in the memory chip, and the deactivation of a master word line 1, 7 or a local word line 3 may be performed by impacting the corresponding word line 1, 3, 7 with a negative voltage that constitutes the highest negative voltage occurring in the memory chip.

The activation of a master word line 1, 7 or of a local word line 3 may also be performed by impacting the corresponding word line 1, 3, 7 with a logic high voltage level, and the deactivation of a master word line 1, 7 or a local word line 3 may be performed by impacting the corresponding word line 1, 3, 7 with a logic low voltage level.

In accordance with a further embodiment, a method further includes the processes of:

activating at least one master word line 7 that is adjacent to the first master word line 1, and generating an electric voltage potential between a first local word line 3 that is associated with the first master word line 1, and a local word line 3 which is adjacent to the first local word line 3 and which is associated to the second master word line 1. Thus, the local word lines 3 of the adjacent master word line 7 can also be stressed among themselves.

Expediently, the method further includes the process of:

marking the memory as defective if a short-circuit was detected between adjacent master word lines of the memory and/or between adjacent local word lines 3. A short-circuit may, for instance, exist already if the measured leakage current between the first master word line 1 and an adjacent master word line 7, and/or between two adjacent local word lines 3 has exceeded a certain threshold value.

As already described above, the semiconductor memory includes a test register that is configured to store the address bits of the master word lines to be selected and/or the local word lines which are to be stressed to each other.

In accordance with one embodiment, the test register includes at least three bits, so that eight different states can be adjusted. If the test register includes four bits, twelve different states of the test mode can be adjusted. Additionally or alternatively, the test register may also be configured to store information about the test mode. Via the adjustment of the test register, adjacent local word lines 3 of the memory may additionally be triggered such that an electric voltage difference is generated between the adjacent local word lines 3.

In accordance with a further embodiment, the memory is a DRAM and includes a number of driver circuit devices 6 via which a respective local word line 3 is coupled with the corresponding selection transistor 4 of the memory cell 4, 5 to the pertinent master word line 1.

The “even”, “odd” selection of the poly silicon word line, also called GC-WL, is achieved by an activation of all MWLs and a suppression of signals for selection via address bits X0 & X1 in the local word line driver 6, as is illustrated in FIG. 3. For the option of activating only every second master word line instead of all master word lines, an additional control line may be incorporated in the MWL decoder.

Although the invention has been described with reference to particular embodiments, it is a matter of fact for a person skilled in the art that different modifications can be performed and equivalents can be exchanged without departing from the scope of the invention. Moreover, many modifications may be performed to adapt a particular situation or a particular material to the teaching of the invention without departing from its scope. It is therefore intended that the invention is not to be restricted to the particular disclosed embodiment, but that it includes all embodiments that are covered by the scope of the enclosed claims.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for testing a semiconductor memory comprising:
providing a number of master word lines and a number of local word lines which can each be triggered via the master word lines, as well as at least one memory cell that stores a data value and is configured to be connected by using the local data lines via a circuit device;
activating a first master word line;
generating an electric voltage difference between the first master word line and an adjacent master word line; and
measuring the leakage current between the first master word line and the adjacent master word line.

2. The method of claim 1, comprising performing the generating of an electric voltage difference between the first master word line and an adjacent master word line by applying opposite electric voltages.

3. The method of claim 1, further comprising:
deactivating at least one master word line that is adjacent to the first master word line.

4. The method of claim 1, further comprising:
activating a number of every second master word line, so that only “even” master word lines with even numbering are activated, while “odd” master word lines with odd numbering are deactivated.

5. The method of claim 1, further comprising:
activating a number of every second master word line, so that only “odd” master word lines with odd numbering are activated, while “even” master word lines with even numbering are deactivated.

6. The method of claim 1, comprising:
performing the activation of a word line by impacting the corresponding word line with a positive voltage constituting the highest positive voltage occurring in the memory chip; and
performing the deactivation of a word line by impacting the corresponding word line with a negative voltage constituting the highest negative voltage occurring in the memory chip.

7. The method of claim 1, comprising:
performing the activation of a word line by impacting the corresponding word line with a logic high voltage level; and
performing the deactivation of a word line by impacting the corresponding word line with a logic low voltage level.

8. The method of claim 1, further comprising:
activating at least one master word line that is adjacent to the first master word line; and
generating an electric voltage potential between a first local word line that is associated with the first master word line, and a local word line that is adjacent to the first local word line and that is associated with the second master word line.

9. The method of claim 1, further comprising:
marking the memory as defective if a short circuit was detected between the first master word line and an adjacent master word line, and/or between two adjacent local word lines.

10. A semiconductor memory comprising:
a number of master word lines and a number of local word lines that can each be triggered via the master word lines;
at least one memory cell that stores a data value and is configured to be connected by using the local data lines via a circuit device,
wherein the memory comprises a test register by the setting of which at least two adjacent master word lines can be triggered during a test method such that an electric voltage difference is generated between the adjacent master word lines.

11. The memory of claim 10, comprising wherein, by the adjustment of the test register, adjacent local word lines of the memory can additionally be triggered such that an electric voltage difference is generated between the adjacent local word lines.

12. The memory of claim 10, wherein the test register comprises at least three bits, so that eight different states can be adjusted.

13. The memory of claim 10, wherein the test register comprises four bits, so that twelve different states can be adjusted.

14. The memory of claim 10, comprising wherein the test register is configured to store information about the test mode.

15. The memory of claim 10, comprising wherein the circuit device is a driver circuit device via which a respective local word line is coupled with the corresponding selection transistor of the memory cell to the pertinent master word line.

16. The memory of claim 10, comprising wherein the memory is a DRAM.

17. An integrated circuit comprising:
activating a first master word line;
generating an electric voltage difference between the first master word line and an adjacent master word line; and
measuring the leakage current between the first master word line and the adjacent master word line.

18. The method of claim 17, comprising performing the generating of an electric voltage difference between the first master word line and an adjacent master word line by applying opposite electric voltages.

19. The method of claim 17, further comprising:
deactivating at least one master word line that is adjacent to the first master word line.

20. The method of claim 17, further comprising:
activating a number of every second master word line, so that only “even” master word lines with even numbering are activated, while “odd” master word lines with odd numbering are deactivated.

21. An integrated circuit test system comprising:
an integrated circuit having a memory, including a number of master word lines and a number of local word lines that can each be triggered via the master word lines, and at least one memory cell that stores a data value and is configured to be connected by using the local data lines via a circuit device; and
wherein the memory comprises a test register by the setting of which at least two adjacent master word lines can be triggered during a test method such that an electric voltage difference is generated between the adjacent master word lines.

22. The integrated circuit of claim 21, comprising wherein, by the adjustment of the test register, adjacent local word lines of the memory can additionally be triggered such that an electric voltage difference is generated between the adjacent local word lines.

23. The integrated circuit of claim 22, comprising wherein the test register is configured to store information about the test mode.

24. The integrated circuit of claim 22, comprising wherein the circuit device is a driver circuit device via which a respective local word line is coupled with the corresponding selection transistor of the memory cell to the pertinent master word line.
